(19) United States
(12) Patent Application Publication
(10) Pub. No.: US 2025/0231471 A1
(43) Pub. Date: Jul. 17, 2025

(54) LIGHT SOURCE DEVICE AND PROJECTOR

(71) Applicant: Sharp NEC Display Solutions, Ltd., Tokyo (JP)

(72) Inventor: Ryosuke KAWASE, Tokyo (JP)

(21) Appl. No.: 19/169,483

(22) Filed: Apr. 3, 2025

Related U.S. Application Data
(63) Continuation of application No. PCT/JP2022/037218, filed on Oct. 5, 2022.

(51) Int. Cl. G03B 21/16; G03B 21/14; G03B 21/20; H05K 7/20

(52) U.S. Cl. CPC G03B 21/16; G03B 21/145; G03B 21/2033; H05K 7/20509

(57) ABSTRACT

A light source device includes a light source part; heat radiation parts which each have a placement surface including a placement region on which the light source part is placed; a case member with which the light source part placed on the placement region is covered by pressing an edge of an opening toward a circumferential region of the placement surface which is located around the placement region; and a wiring board which is connected to the light source part and extends from the light source part to an outside of the placement surface along the placement surface. The light source part includes a substrate and a connector which is installed in a main surface of the substrate and connected to the wiring board. The connector is located to have a gap in a direction in which it is away from the placement region by bringing a surface of the substrate which faces an opposite side to the main surface into contact with the placement region. The circumferential region is located to have a gap in a direction in which it is away from the placement region by providing a step between the circumferential region and the placement region.

### TECHNICAL FIELD

The present disclosure relates to a light source device and a projector.

### BACKGROUND ART

Patent Document 1 discloses a light source device which includes a light source part having a light emitting element installed in a substrate and a heat radiation part thermally connected to the light source part. In the light source device of Patent Document 1, the light source part is placed on a flat placement surface of the heat radiation part.

### CITATION LIST

### Patent Document

[Patent Document 1]
[Patent Document 1] Japanese Unexamined Patent Application, First Publication No. 2020-042147

### SUMMARY OF INVENTION

### Technical Problem

Incidentally, in this type of light source device, ensuring the heat radiation performance of the light source part, dust prevention measures for the light source part, and electrical reliability of the light source device is required.

The present invention was made in consideration of the above-described circumstances, and an object of the present invention is to provide a light source device and a projector which can ensure the heat radiation performance of a light source part, dust prevention measures for the light source part, and electrical reliability.

A first aspect of the present invention is a light source device which includes: a light source part; heat radiation parts which each have a placement surface including a placement region on which the light source part is placed; a case member with which the light source part placed on the placement region is covered by pressing an edge of an opening toward a circumferential region of the placement surface which is located around the placement region; and a wiring board which is connected to the light source part and extends from the light source part to an outside of the placement surface along the placement surface. The light source part includes a substrate and a connector which is installed in a main surface of the substrate and connected to the wiring board. The connector is located at an interval from the placement region in a direction away therefrom by bringing a surface of the substrate which faces an opposite side to the main surface into contact with the placement region. The circumferential region is located to have a gap in a direction in which it is away from the placement region by providing a step between the circumferential region and the placement region.

A second aspect of the present invention is a projector which includes the light source device.

### Advantageous Effects of Invention

According to the present invention, it is possible to ensure the heat radiation performance of the light source part, dust prevention measures for the light source part, and electrical reliability of the light source device.

### BRIEF DESCRIPTION OF DRAWINGS

FIG. 1 A perspective view showing an exterior form of a projector according to a first embodiment of the present invention.

FIG. 2 A perspective view showing a light source device according to the first embodiment of the present invention.

FIG. 3 A cross-sectional view showing the light source device of FIG. 2.

FIG. 4 An exploded perspective view showing a state in which a case member is removed from a heat radiation part in the light source device of FIG. 2.

FIG. 5 An exploded perspective view showing a state in which a light source part and a wiring board are removed from the heat radiation part in FIG. 4.

FIG. 6 An enlarged view of a region VI in FIG. 3.

FIG. 7 An enlarged view of a main part of FIG. 4.

FIG. 8 A perspective view showing a light source device according to a second embodiment of the present invention.

FIG. 9 An exploded perspective view showing a state in which a case member is removed from a heat radiation part in the light source device of FIG. 8.

FIG. 10 An exploded perspective view showing a state in which a wiring board is removed from the heat radiation part in FIG. 9.

FIG. 11 A plan view showing a constitution in which the wiring board and a plurality of light source parts are connected in the light source device of the second embodiment.

### DESCRIPTION OF EMBODIMENTS

### First Embodiment

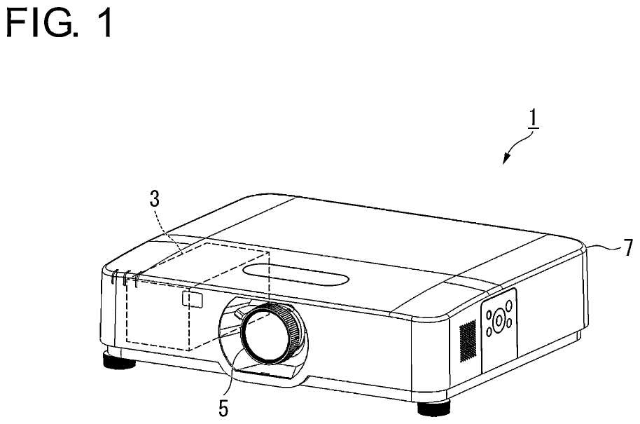

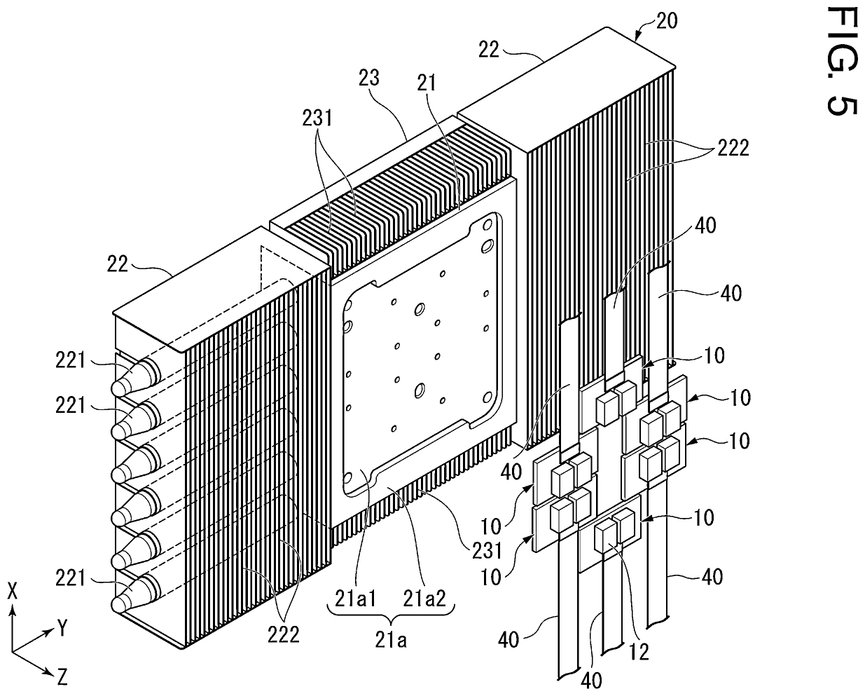

A first embodiment of the present invention will be described below with reference to FIGS. 1 to 7.

A projector 1 according to this embodiment shown in FIG. 1 is a device which projects image light (video) onto a display surface such as a screen. The projector 1 includes a light source device 3, an image light formation device (not shown), a projection device 5, and a housing 7. The housing 7 has the light source device 3, the image light formation device, and the projection device 5 accommodated therein.

The image light formation device creates image light on the basis of light output from the light source device 3 which will be described below. Although not shown in the drawings, an optical engine includes a light modulation element such as a Digital Micromirror Device (DMD) or a liquid crystal panel, electronic components which control the light modulation element, or the like.

The projection device 5 expands image light output from the image light formation device and projects the expanded image light onto a display surface such as a screen.

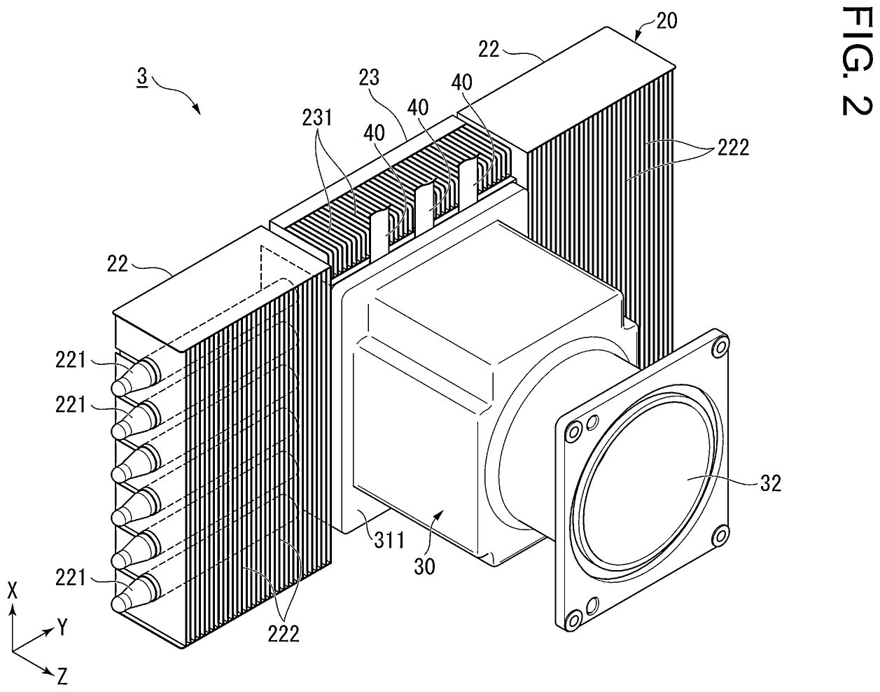

As shown in FIGS. 2 to 4, the light source device 3 includes light source parts 10, a heat radiation part 20, a case member 30, and a wiring board 40.

The light source parts 10 emits light. The light source device 3 in this embodiment has the plurality of (six in the shown example) light source parts 10.

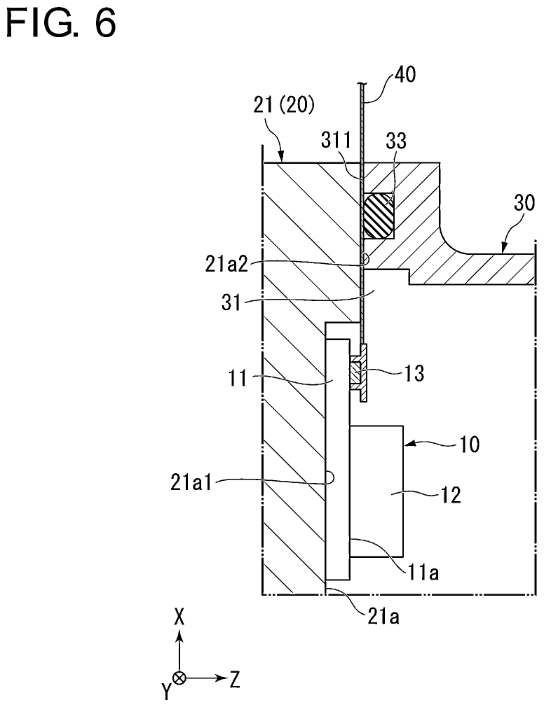

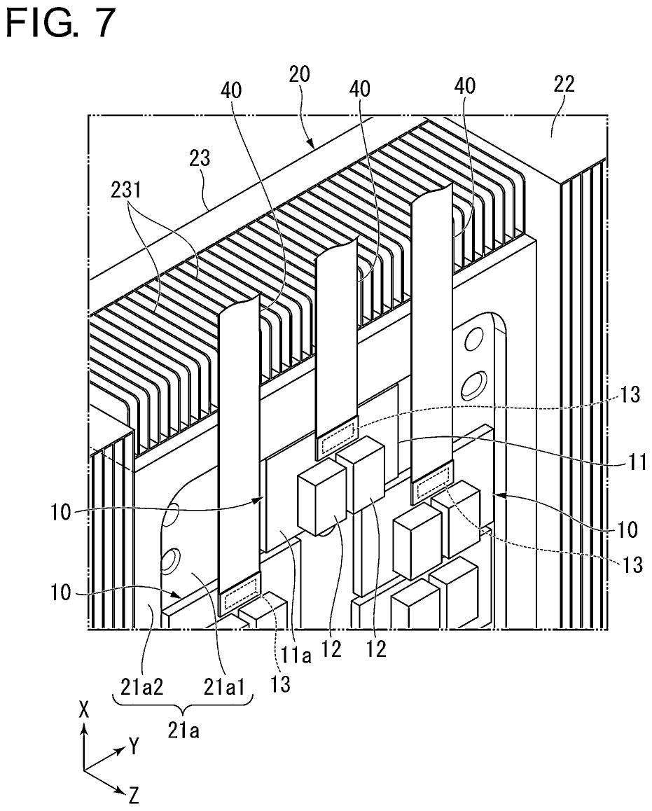

As shown in FIGS. 6 and 7, each of the light source parts 10 includes a substrate 11, and a light emitting element 12 and a connector 13 which are installed in a main surface 11a of the substrate 11. Although the light emitting element 12 may be, for example, a Light Emitting Diode (LED) or the like, in this embodiment, the light emitting element 12 is a laser diode. The light emitting element 12 in this embodiment emits laser light within a blue wavelength range. That is to say, the light source parts 10 in this embodiment correspond to a laser substrate. Although the number of light emitting elements 12 included in the light source parts 10 may be two as in the shown example, the present invention is not limited thereto.

Although not shown in the drawings, the substrate 11 also has a thermistor which measures a temperature of the light source parts 10 installed therein. The substrate 11 has an electrical wiring (not shown) which connects the light emitting element 12 and the thermistor to the connector 13 formed therein. The connector 13 is connected to the wiring board 40 which will be described later.

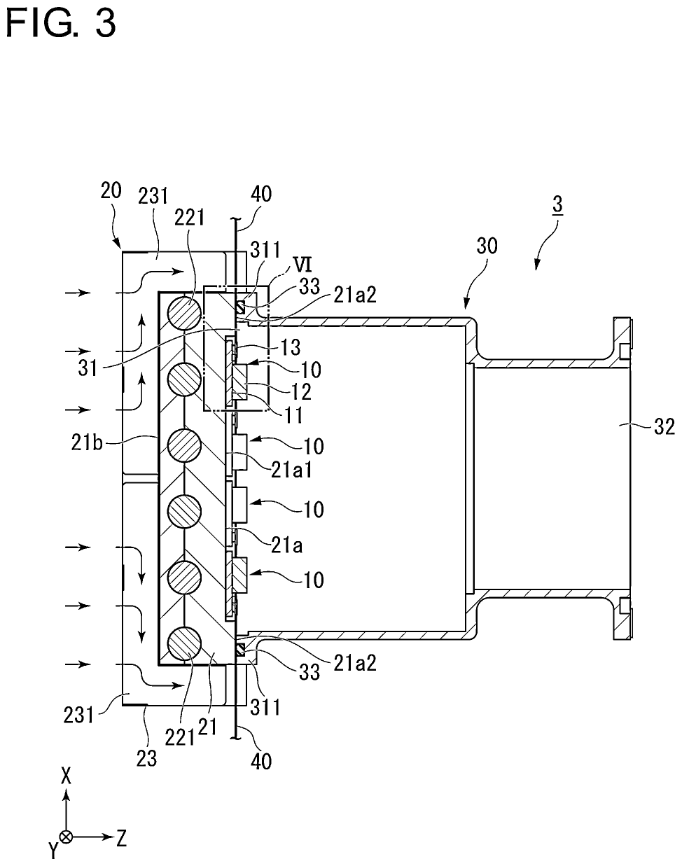

As shown in FIGS. 3 to 5, the heat radiation part 20 has a placement surface 21a which includes a placement region 21al and a circumferential region 21a2. The placement region 21al which has the light source parts 10 placed thereon is formed to be generally flat. The circumferential region 21a2 is a flat surface located around the placement region 21a1.

In FIGS. 2 to 7, a first direction along the placement surface 21a is indicated as an X-axis direction and a second direction along the placement surface 21a which is orthogonal to the first direction is indicated as a Y-axis direction. Furthermore, a direction perpendicular to that of the placement surface 21a is indicated as a Z-axis direction. In the following description, a direction away from the placement surface 21a in the Z-axis direction (the Z-axis forward direction) may be referred to as an “upward side.”

As shown in FIGS. 3 to 5, the circumferential region 21a2 is located above and spaced apart from the placement region 21a1. There is a step between the placement region 21al and the circumferential region 21a2.

As shown in FIGS. 6 and 7, the substrate 11 of the light source parts 10 is disposed on the placement region 21al so that they overlap. In this state, a surface of the substrate 11 which faces an opposite side to the main surface 11a is in contact with the placement region 21a1. Although the substrate 11 may be in direct contact with the placement region 21a1, the substrate 11 may be in indirect contact with the placement region 21a1. For example, heat transfer from the substrate 11 to the heat radiation part 20 may be improved using a thermally conductive grease provided between the substrate 11 and the placement region 21a1.

In a state in which the light source parts 10 are placed on the placement region 21a1, the light generated in the light emitting elements 12 of the light source parts 10 is mainly directed in a direction in which it goes away from the placement surface 21a (the Z-axis forward direction). Furthermore, the connector 13 of the light source part 10 is located above and spaced apart from the placement region 21al by a thickness of the substrate 11.

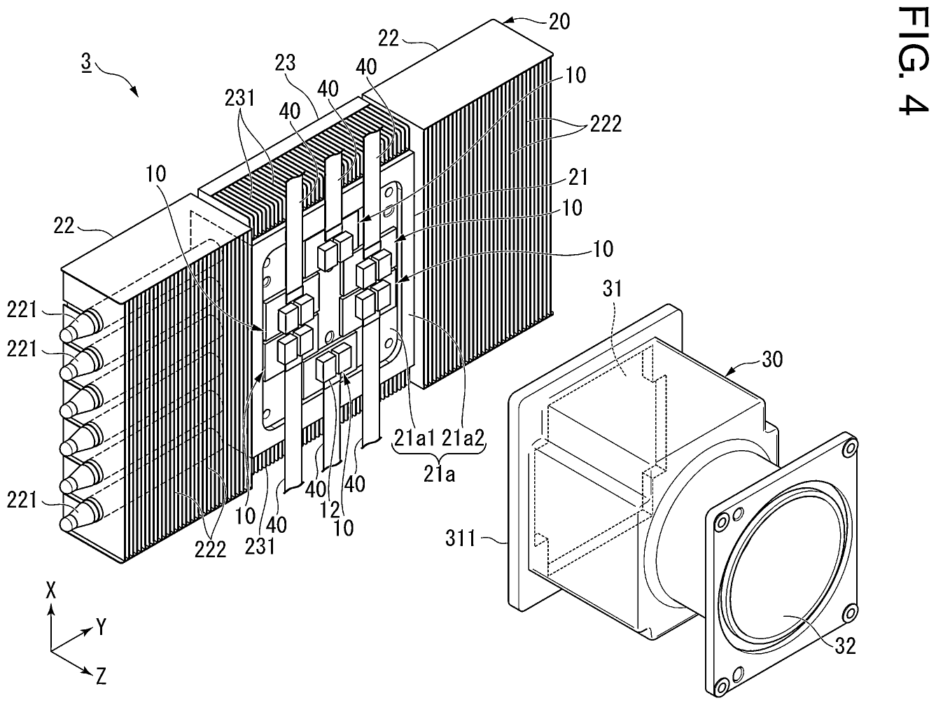

As shown in FIGS. 3 and 4, the plurality of light source parts 10 are placed in the placement region 21al so that the wiring board 40 which is connected to the connector 13 of each of the light source parts 10 can extend in the first direction from each of the light source parts 10 without interfering with the other of the light source parts 10. Specifically, the plurality of light source parts 10 are placed in the placement region 21al so that another of the light source parts 10 is not disposed between two light source parts 10 in the first direction.

An area of the placement surface 21a is set to be small in consideration of the heat radiation efficiency of the light source parts 10 through the heat radiation part 20. In other words, a ratio of an occupation area of the plurality of light source parts 10 to the area of the placement surface 21a is set to be large. For this reason, a gap between the light source parts 10 placed in the placement region 21al and an edge of the placement region 21al (a boundary with the circumferential region 21a2) is reduced.

As shown in FIGS. 3 to 5, the heat radiation part 20 of this embodiment has a base part 21 including the placement surface 21a, extended heat radiation parts 22, and a rear-surface heat radiation part 23.

The base part 21 is formed in a plate shape in which the Z-axis direction is defined as a thickness direction thereof. The base part 21 is, for example, made of a highly conductive material such as copper.

The extended heat radiation parts 22 each extend from both ends of the base part 21 in the second direction (the Y-axis direction) along the placement surface 21a. The extended heat radiation part 22 may extend from only one end of the base part 21, for example, in the second direction. The extended heat radiation part 22 is configured to radiate heat by flowing air through the extended heat radiation parts 22 in the direction which is orthogonal to that of the placement surface 21a (the Z-axis direction).

Specifically, the extended heat radiation part 22 include heat pipes 221 and a plurality of heat radiation fins 222 attached to the heat pipes 221. The heat pipes 221 each extend in the second direction from an end of the base part 21. In the embodiment, the heat pipe 221 passes through the base part 21 in the second direction and extends from both ends of the base part 21. The heat pipes 221 are arranged in the first direction (the X-axis direction).

Each of the plurality of heat radiation fins 222 of the extended heat radiation parts 22 is formed in a plate shape in which the direction in which the heat pipes 221 extend (the Y-axis direction) is defined as a thickness direction thereof. The plurality of heat radiation fins 222 on both sides of the base part 21 in the second direction are arranged to have gaps therebetween in the second direction. The heat pipes 221 are attached to the plurality of heat radiation fins 222 to pass through the heat radiation fins 222 in the thickness direction thereof.

In the extended heat radiation parts 22 configured in this way, air can flow between the plurality of heat radiation fins 222 in the direction which is orthogonal to that of the placement surface 21a (the Z-axis direction).

The rear-surface heat radiation part 23 has a plurality of heat radiation fins 231 provided on a rear surface 21b of the base part 21 which faces an opposite side to the placement surface 21a. The rear surface 21b of the base part 21 is a surface which is generally parallel to the placement surface 21a. In the following description, the direction along the rear surface 21b corresponds to the first direction (the X-axis direction) and the second direction (the Y-axis direction) and the direction which is orthogonal to that of the rear surface 21b corresponds to the Z-axis direction.

Each of the plurality of heat radiation fins 231 is formed in a plate shape in which the second direction along the rear surface 21b of the base part 21 is defined as a thickness direction. Furthermore, each of the heat radiation fins 231 extends in the first direction along the rear surface 21b of the base part 21. The plurality of heat radiation fins 231 are arranged to have gaps between these in the second direction, as in the heat radiation fins 222 in the extended heat radiation parts 22.

The plurality of heat radiation fins 231 each extend from both ends of the base part 21 in the first direction. Thus, on both sides of the base part 21 in the first direction, air can pass in a direction which is orthogonal to that of the rear surface 21b (the Z-axis direction) so that air passes between the plurality of heat radiation fins 231 of the rear-surface heat radiation part 23. The plurality of heat radiation fins 231 may, for example, extend from only one end of the base part 21 in the first direction.

The heat radiation part 20 configured as described above plays a role in cooling the light source parts 10. Specifically, heat generated in the light source parts 10 placed in the placement region 21al is transferred to the base part 21 and then mainly to the heat pipes 221 and the plurality of heat radiation fins 222 of the extended heat radiation parts 22. Moreover, by flowing air between the plurality of heat radiation fins 222 in the direction which is orthogonal to that of the placement surface 21a (the Z-axis direction), specifically by flowing air in the Z-axis forward direction, the heat transferred from the light source parts 10 to the plurality of heat radiation fins 222 of the extended heat radiation parts 22 is radiated.

Also, a part of the heat transferred to the base part 21 is also transferred to the plurality of heat radiation fins 231 in the rear-surface heat radiation part 23. Furthermore, by flowing air between the plurality of heat radiation fins 231 of the rear-surface heat radiation part 23 in the direction which is orthogonal to that of the placement surface 21a (the Z-axis direction), specifically, by flowing air as indicated by the arrows in FIG. 3, the heat transferred from the light source parts 10 to the plurality of heat radiation fins 231 of the rear-surface heat radiation part 23 is radiated.

As shown in FIGS. 3 and 4, the case member 30 covers the light source parts 10 placed on the placement region 21al to prevent dust from adhering to the light source parts 10 (particularly the light emitting element 12). The case member 30 has two openings 31 and 32 (a first opening 31 and a second opening 32). As shown in FIGS. 3 and 6, an edge 311 of the first opening 31 of the case member 30 is pressed toward the circumferential region 21a2 of the placement surface 21a. In this embodiment, the edge 311 of the first opening 31 is in contact with the circumferential region 21a2 of the placement surface 21a. An elastic body 33 such as an O-ring is provided on the edge 311 of the first opening 31. By pressing the elastic body 33 against the circumferential region 21a2, the edge 311 of the first opening 31 can be brought into tight contact with the circumferential region 21a2 without leaving a gap.

As shown in FIGS. 2 and 3, the second opening 32 of the case member 30 is formed to allow light from the light source parts 10 to be emitted outside of the case member 30 when the case member 30 is attached to the placement surface 21a of the heat radiation part 20. For example, the image light formation device described above may be attached to the second opening 32 of the case member 30. In this embodiment, an optical unit (not shown) of the light source device 3 is attached to the second opening 32 of the case member 30. The optical unit appropriately processes light (blue light) from the light source parts 10 and emits white light to the image light formation device.

The first opening 31 of the case member 30 is blocked using the heat radiation part 20 and the second opening 32 of the case member 30 is blocked using the optical unit (or the image light formation device or the like), thereby preventing or suppressing dust from entering the inside of the case member 30.

The case member 30 is formed not to protrude outward (in the X-axis direction, the Y-axis direction) from an edge of the placement surface 21a. Thus, this can prevent a flow of air passing between the plurality of heat radiation fins 222 and 231 of the extended heat radiation parts 22 and the rear-surface heat radiation part 23 from the rear surface 21b side of the base part 21 toward the placement surface 21a side (Z-axis forward direction) around the base part 21 from being obstructed by the case member 30.

As shown in FIGS. 6 and 7, the wiring board 40 is connected to the connector 13 of each of the light source parts 10. That is to say, the wiring board 40 is provided for each of the plurality of light source parts 10. The wiring board 40 which is connected to the light source parts 10 extends from the light source parts 10 to the outside of the placement surface 21a along the placement surface 21a. The wiring board 40 electrically connects the light source parts 10 to external devices (for example, a power source, a control device, or the like).

The wiring board 40 is formed in a long and narrow strip shape and is disposed so that longitudinal and width directions thereof are aligned along the placement surface 21a. The wiring board 40 is a flexible wiring board which can be easily bent in the thickness direction of the wiring board 40 at any intermediate portion in a longitudinal direction thereof.

As shown in FIGS. 3 and 4, each of the wiring boards 40 extends in the first direction (the X-axis direction) along the placement surface 21a. In this embodiment, the wiring board 40 extends from the light source parts 10 which is installed in a region on one side in the first direction (the side in the X-axis forward direction) of the placement region 21al and extends from the light source part 10 toward one side in the first direction. Furthermore, the wiring board 40 which extends from the light source part 10 installed in the region on the other side (the side in a X-axis rearward direction) of the placement region 21al in the first direction extends from the light source parts 10 toward the other side in the first direction.

The wiring board 40 arranged as described above is disposed so that the wiring board 40 and a part in a circumferential direction of the circumferential region 21a2 of the placement surface 21a overlap and the wiring board 40 is disposed between a part in the radial direction of the circumferential region 21a2 and the edge 311 of the first opening 31 of the case member 30 (refer to particularly FIGS. 3 and 6). For this reason, the edge 311 of the first opening 31 of the case member 30 is in contact with the remaining portion in the radial direction of the circumferential region 21a2. Since the wiring board 40 that is a flexible wiring board has a small thickness, a step between the circumferential region 21a2 and the wiring board 40 disposed thereon is small. For this reason, when the edge 311 of the first opening 31 of the case member 30 is pressed toward the circumferential region 21a2, the occurrence of a gap between the circumferential region 21a2 and the case member 30 due to the wiring board 40 can be suppressed or prevented.

In the light source device 3 of the first embodiment and the projector 1 including the light source device 3, it is possible to ensure the heat radiation performance of the light source parts 10, the dust prevention measures of the light source parts 10, and the electrical reliability. These points will be described below.

The edge 311 of the first opening 31 of the case member 30 can be pressed toward the circumferential region 21a2 of the placement surface 21a, and specifically is in contact with the circumferential region 21a2, thereby ensuring dust prevention measures for the light source parts 10.

Moreover, in the light source device 3 of this embodiment, the circumferential region 21a2 of the placement surface 21a which is in contact with the edge 311 of the first opening 31 of the case member 30 is located above the placement region 21al to have a gap, as in the connector 13 of the light source parts 10. For this reason, it is possible to ensure the electrical reliability of the light source device 3. This point will be described below.

When the connector 13 of the light source part 10 is located above the placement region 21al to have a gap, the wiring board 40 which is connected to the connector 13 is located above the placement region 21al to have a gap near the connector 13 (refer to FIG. 6). In addition, in order to take into account the heat radiation efficiency of the light source parts 10, the gap between the light source parts 10 placed in the placement region 21al and the circumferential region 21a2 is small.

For this reason, for example, when there is no step between the placement region 21al and the circumferential region 21a2, the wiring board 40 which extends from the light source parts 10 is located above the circumferential region 21a2 to have a gap therebetween. Thus, if the wiring board 40 is disposed between the edge 311 of the first opening 31 of the case member 30 and the circumferential region 21a2, a force acting on the connection portion (the connector 13) between the light source parts 10 and the wiring board 40 will become large. As a result, the electrical reliability of the connection is reduced.

On the other hand, when the circumferential region 21a2 is located above the placement region 21al to have a gap therebetween, the wiring board 40 which extends from the light source parts 10 can be located on the circumferential region 21a2 so that the gap with respect to the circumferential region 21a2 is small or so that the gap is eliminated. Thus, even when the wiring board 40 is disposed between the edge 311 of the first opening 31 of the case member 30 and the circumferential region 21a2, a force acting on the connection portion (the connector 13) between the light source parts 10 and the wiring board 40 can be reduced or eliminated. Therefore, it is possible to ensure the electrical reliability of the light source device 3.

The above-described effect (the effect of ensuring the electrical reliability of the light source device 3 by locating the circumferential region 21a2 above the placement region 21al to have a gap) is effective when the size of the base part 21 when viewed in a plan view (that is, an area of the placement surface 21a) is small and a distance between the light source parts 10 placed on the placement surface 21a and a circumference of the placement surface 21a when viewed in a plan view is small. That is to say, according to this embodiment, while keeping the area of the placement surface 21a small, the connection between the light source parts 10 and the wiring board 40 is ensured, and the electrical reliability of the light source device 3 can be ensured.

Moreover, by making the area of the placement surface 21a smaller, even if there are restrictions on an installation space of the light source device 3 in the projector 1, it is possible to secure a space around the base part 21 (the placement surface 21a) for placing other components of the heat radiation part 20 (the heat radiation fins 222 and 231 of the extended heat radiation parts 22 and the rear-surface heat radiation part 23). Thus, by circulating air through heat radiation fins 222 and 231 disposed around the placement surface 21a, it is possible to ensure the heat radiation performance of the light source parts 10.

Also, in the light source device 3 and the projector 1 of the first embodiment, the heat radiation part 20 has the extended heat radiation parts 22 which extend from the end of the base part 21 in the second direction (the Y-axis direction) along the placement surface 21a. The extended heat radiation parts 22 dissipate heat by flowing air in the direction which is orthogonal to that of the placement surface 21a (the Z-axis direction). On the other hand, the wiring board 40 which extends from the light source part 10 placed on the placement surface 21a extends in the first direction along the placement surface 21a.

For this reason, even if the wiring board 40 extends along the placement surface 21a to the outside of the placement surface 21a, it is possible to prevent the overlapping of the wiring board 40 and the extended heat radiation parts 22 in the direction which is orthogonal to that of the placement surface 21a. Thus, this makes it possible to prevent the wiring board 40 from obstructing a flow of air in the extended heat radiation parts 22. Therefore, it is possible to improve the heat radiation efficiency of the light source parts 10.

Also, in the light source device 3 and the projector 1 of this embodiment, the heat radiation part 20 has the plurality of heat radiation fins 231 which are provided on the rear surface 21b of the base part 21 and extend in the first direction (the X-axis direction). The plurality of heat radiation fins 231 extend from the end of the base part 21 in the first direction (the X-axis direction).

Thus, by flowing air in the first direction through the portions of the heat radiation fins 231 which protrude from the end of the base part 21, it is possible to efficiently radiate the heat transferred from the light source parts 10 to the heat radiation fins 231. Therefore, it is possible to improve the heat radiation efficiency of the light source parts 10.

Furthermore, in the light source device 3 and the projector 1 of this embodiment, the wiring board 40 is a flexible wiring board. Thus, the wiring board 40 can be freely curved outside the placement surface 21a (the circumferential region 21a2).

In the first embodiment, the wiring board 40 is not limited to a flexible wiring board and may be, for example, a rigid wiring board which does not undergo bending deformation.

### Second Embodiment

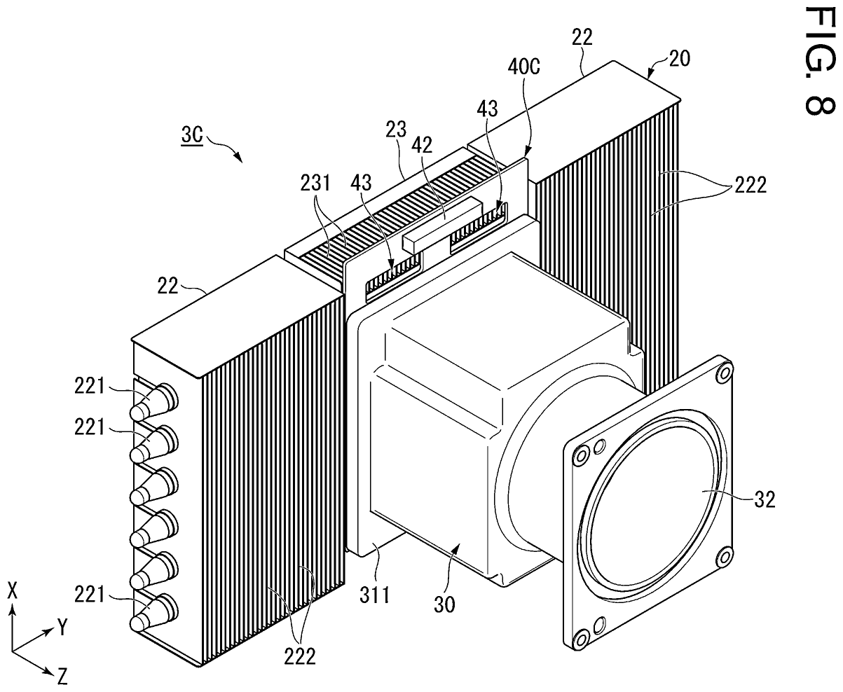

A second embodiment of the present invention will be described below with reference to FIGS. 8 to 11. In the following description, constituent elements that are the same as those already described will be denoted by the same reference numerals and duplicated description thereof will be omitted.

As shown in FIGS. 8 to 10, a light source device 3C of the second embodiment is configured as in the light source device 3 of the first embodiment, except for a wiring board 40C and is applicable to the projector 1 of the first embodiment. The number of wiring boards 40C provided in the light source device 3C in this embodiment is one. The wiring board 40C is connected to a connector 13 of each of a plurality of light source parts 10. The wiring board 40C is disposed so that the wiring board 40C and the entire circumferential region 21a2 in the radial direction of a placement surface 21a of a base part 21 overlap. For this reason, the wiring board 40C is disposed between the circumferential region 21a2 of the base part 21 and an edge 311 of a first opening 31 of a case member 30. The wiring board 40C protrudes from the circumferential region 21a2 toward one side in the first direction (the side in the X-axis forward direction).

The wiring board 40C in this embodiment is a rigid wiring board which does not curve in the thickness direction thereof.

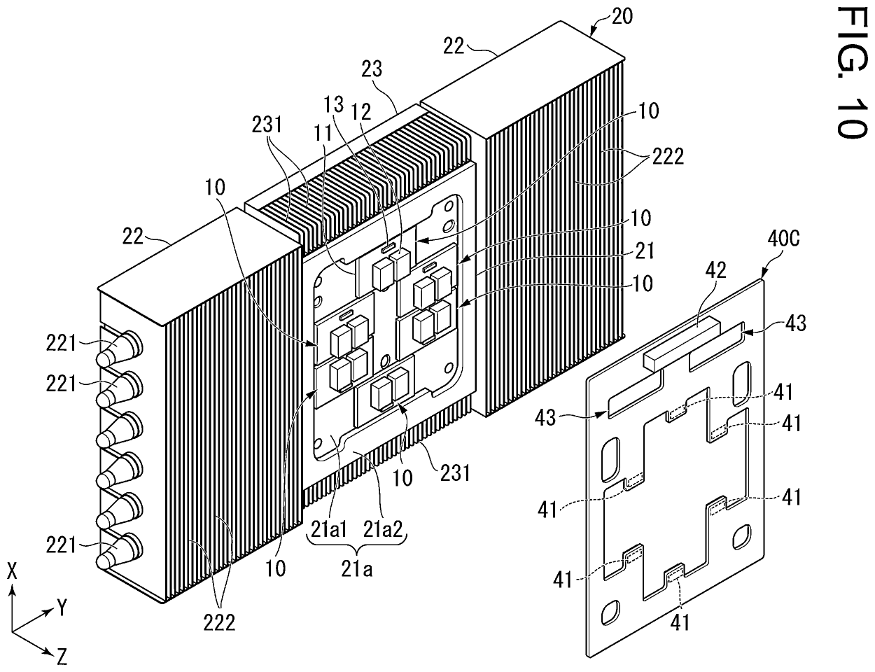

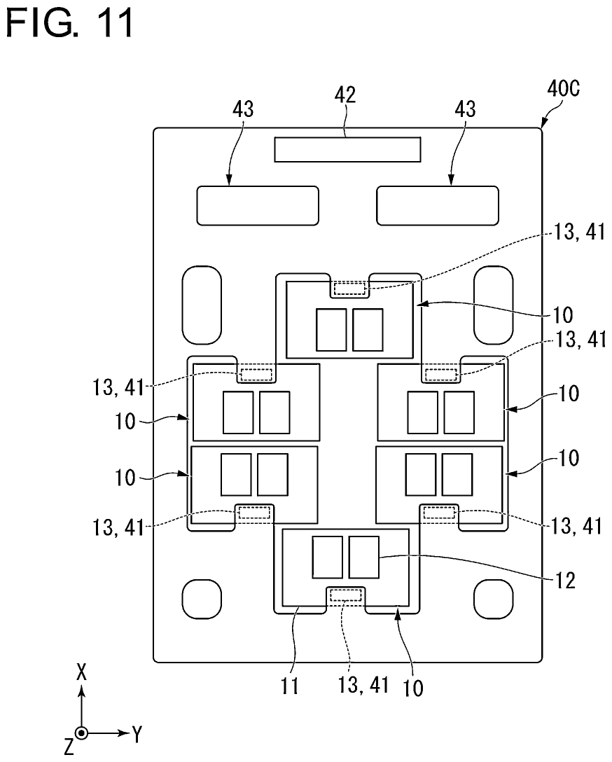

As shown in FIGS. 10 and 11, the wiring board 40C has a plurality of light-source-part connection connectors 41 and one external connection connector 42. The plurality of light-source-part connection connectors 41 are electrically connected to each of the connectors 13 of the plurality of light source parts 10 which are disposed in the placement region 21a1. The external connection connector 42 is electrically connected to the plurality of light-source-part connection connectors 41 via a connection wiring (not shown) formed on the wiring board 40C. A predetermined device (for example, a power source which supplies electric power to the plurality of light source parts 10 or a control device which controls an operation of the plurality of light source parts 10) is connected to the external connection connector 42.

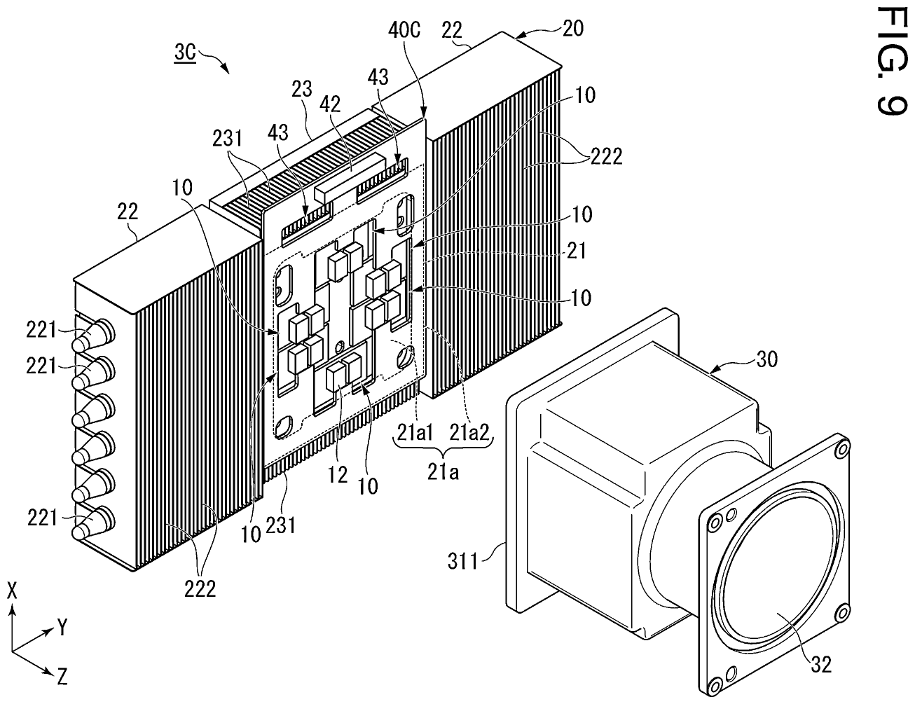

As shown in FIGS. 8 and 9, the external connection connector 42 is disposed outside the circumferential region 21a2 in a state in which the wiring board 40C is disposed so that the wiring board 40C and the circumferential region 21a2 overlap. Specifically, the external connection connector 42 is provided in a portion of the wiring board 40C which protrudes from the circumferential region 21a2 toward one side in the first direction (the side in the X-axis forward direction). The external connection connector 42 is located so that the external connection connector 42 and heat radiation fins 231 of a rear-surface heat radiation part 23 do not overlap in the direction which is orthogonal to that of the placement surface 21a (the Z-axis direction).

In the wiring board 40C of this embodiment, a through hole 43 which passes through the wiring board 40C in a plate thickness direction thereof is formed. The through hole 43 is formed in a portion of the wiring board 40C which is located outside the circumferential region 21a2. The through hole 43 passes through the wiring board 40C in the direction which is orthogonal to that of the placement surface 21a (the Z-axis direction) in a state in which the wiring board 40C is disposed so that the wiring board 40C and the circumferential region 21a2 overlap.

As shown in FIGS. 10 and 11, the through hole 43 is located between the plurality of light-source-part connection connectors 41 and the external connection connector 42. The through hole 43 is formed not to impede the formation of the connection wiring which connects the plurality of light-source-part connection connectors 41 and the external connection connector 42. Although the through hole 43 is formed in a plurality of parts not to impede the formation of the connection wiring described above in the shown example, the present invention is not limited thereto. As shown in FIGS. 8 and 9, the through hole 43 is formed in a portion of the wiring board 40C which protrudes from the circumferential region 21a2 toward one side in the first direction (the side in the X-axis forward direction). The through hole 43 is located so that the through hole 43 and the heat radiation fins 231 of the rear-surface heat radiation part 23 overlap in the direction which is orthogonal to that of the placement surface 21a (the Z-axis direction).

According to the light source device 3C of the second embodiment, the same effect as in the first embodiment is achieved. For example, an edge 311 of the first opening 31 of the case member 30 can be pressed toward the circumferential region 21a2 of the placement surface 21a, thereby ensuring dust prevention measures for the light source parts 10.

Specifically, the wiring board 40C is disposed between the circumferential region 21a2 and the edge 311 of the first opening 31 of the case member 30. For this reason, compared to when the wiring board 40C and only a part in the radial direction of the circumferential region 21a2 overlap, even if the wiring board 40C is thick, the occurrence of a gap between the circumferential region 21a2 and the case member 30 can be suitably suppressed or prevented. Therefore, even if the wiring board 40C is thick, it is possible to easily ensure the dust prevention measures of the light source parts 10. Also, in the light source device 3C of the second embodiment, the plurality of light source parts 10 are connected to one of the external connection connectors 42 of the wiring board 40C which is disposed outside the circumferential region 21a2. Thus, a predetermined device (for example, a power source or a control device) can be easily connected to the plurality of light source parts 10 by simply connecting the predetermined device to one of the external connection connectors 42 on the wiring board 40C.

Furthermore, in the light source device 3C of the second embodiment, the through hole 43 which passes through the wiring board 40C in the plate thickness direction is formed in a portion of the wiring board 40C which is located outside the circumferential region 21a2. For this reason, air can pass through the through hole 43 of the wiring board 40C in the plate thickness direction of the wiring board 40C (that is, the direction which is orthogonal to that of the placement surface 21a). Thus, even if a portion of the wiring board 40C which is located outside the circumferential region 21a2 and the plurality of heat radiation fins 231 of the rear-surface heat radiation part 23 which protrudes outside the circumferential region 21a2 overlap in the orthogonal direction which is orthogonal to that of the placement surface 21a (the Z-axis direction), the wiring board 40C can be prevented from impeding a flow of air in the plurality of heat radiation fins 231. Therefore, it is possible to suppress a decrease in the heat radiation efficiency of the light source parts 10 due to the wiring board 40C.

In addition, in the light source device 3C of the second embodiment, the wiring board 40C is a rigid wiring board and does not bend like a flexible wiring board. For this reason, the positioning of the wiring board 40C relative to the connector 13 of the light source parts 10 can be easily performed, as compared to when the wiring board 40C is a flexible wiring board. This effect is particularly effective when there are a plurality of connectors 13 of the light source parts 10 which are connected to the wiring board 40C.

In the second embodiment, the external connection connector 42 may be provided in a portion of the wiring board 40C which protrudes from the circumferential region 21a2 toward the other side in the first direction (the side in the X-axis rearward direction). Moreover, the external connection connector 42 may be provided, for example, at a portion of the wiring board 40C which protrudes in the second direction (the Y-axis direction) from the circumferential region 21a2. In this case, it is preferable that the external connection connector 42 and the heat radiation fins 222 of the extended heat radiation parts 22 do not overlap in the direction which is orthogonal to that of the placement surface 21a (Z-axis direction).

In the second embodiment, the through hole 43 may be formed, for example, in a portion of the wiring board 40C which protrudes from the circumferential region 21a2 to the other side in the first direction (the side in the X-axis rearward direction). Furthermore, the through hole 43 may be formed, for example, in a portion of the wiring board 40C which protrudes in the second direction (the Y-axis direction) from the circumferential region 21a2. In this case, the through hole 43 may be located so that the through hole 43 and the heat radiation fins 222 of the extended heat radiation parts 22 overlap in the direction which is orthogonal to that of the placement surface 21a (Z-axis direction). In the configuration in this way, the wiring board 40 can be prevented from impeding a flow of air in the heat radiation fins 222 of the extended heat radiation parts 22, thereby suppressing a decrease in the heat radiation efficiency of the light source parts 10 based on the wiring board 40C.

In the second embodiment, the wiring board 40C is not limited to a rigid wiring board and may be, for example, a flexible wiring board which is capable of being curved and deformed.

The through hole 43 in the second embodiment may be applied to, for example, the wiring board 40 in the first embodiment.

Although the embodiment of the present invention has been described above, the present invention is not limited to the above embodiment and can be modified appropriately without departing from the spirit thereof.

In the present invention, the wiring board 40 which extends in the first direction from the light source parts 10 may be curved to extend above the placement surface 21a (in the Z-axis forward direction), for example, outside the placement surface 21a (outside the case member 30). In this case, since the wiring board 40 and the heat radiation fins 231 which protrudes from the end of the base part 21 do not overlap in the first direction, the wiring board 40 can be prevented from obstructing a flow of air in the heat radiation fins 231. Therefore, it is possible to improve the heat radiation efficiency of the light source parts 10.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### REFERENCE SIGNS LIST

1 Projector
3, 3C Light source device
10 Light source part
11 Substrate
11a Main surface
12 Light emitting element
13 Connector
20 Heat radiation part
21 Base part
21a Placement surface
21al Placement region
21a2 Circumferential region
21b Rear surface
22 Extended heat radiation part
221 Heat pipe
222 Heat radiation fin
23 Rear-surface heat radiation part
231 Heat radiation fin
30 Case member
31 First opening
311 Edge of first opening 31
32 Second opening
40, 40C Wiring board
41 Light-source-part connection connector
42 External connection connector
43 Through hole

1. A light source device, comprising:
a light source part;
heat radiation parts which each have a placement surface including a placement region on which the light source part is placed;
a case member with which the light source part placed on the placement region is covered by pressing an edge of an opening toward a circumferential region of the placement surface which is located around the placement region; and
a wiring board which is connected to the light source part and extends from the light source part to an outside of the placement surface along the placement surface,
wherein the light source part includes a substrate and a connector which is installed in a main surface of the substrate and connected to the wiring board,
the connector is located at an interval from the placement region in a direction away therefrom by bringing a surface of the substrate which faces an opposite side to the main surface into contact with the placement region, and
the circumferential region is located at an interval from the placement region in a direction away therefrom by providing a step between the circumferential region and the placement region.

2. The light source device according to claim 1, wherein the wiring board is disposed so that the wiring board and the entire circumferential region in the radial direction overlap and is disposed between the circumferential region and the case member.

3. The light source device according to claim 2, wherein the placement region has a plurality of the light source parts displaced thereon, and
the wiring board has one external connection connector which is electrically connected to the connector of each of the plurality of the light source parts and disposed outside the circumferential region.

4. The light source device according to claim 1, wherein the wiring board is disposed so that the wiring board and a part in a radial direction of the circumferential region overlap and is disposed between the part in the radial direction of the circumferential region and the case member, and
the case member is in contact with the remaining portion in the radial direction of the circumferential region.

5. The light source device according to claim 1, wherein a through hole which passes through the wiring board in a plate thickness direction thereof is formed in a portion of the wiring board which is located outside the circumferential region.

6. The light source device according to claim 1 t, wherein the wiring board extends in a first direction along the placement surface,
the heat radiation part includes a base part which includes the placement surface and an extended heat radiation part which protrudes from an end of the base part in a second direction which is orthogonal to the first direction along the placement surface, and
the extended heat radiation part is configured to radiate heat by flowing air through the extended heat radiation part in the direction which is orthogonal to the placement surface.

7. The light source device according to claim 1, wherein the wiring board extends in a first direction along the placement surface,
the heat radiation part has a base part which includes the placement surface and a plurality of heat radiation fins which are provided on a rear surface of the base part facing an opposite side to the placement surface and extend in the first direction, and
the plurality of heat radiation fins protrude from an end of the base part in the first direction.

8. The light source device according to claim 1, wherein the wiring board is a rigid wiring board.

9. The light source device according to claim 1, wherein the wiring board is a flexible wiring board.

10. A projector, comprising: a light source device, the light source device comprising:
a light source part;
heat radiation parts which each have a placement surface including a placement region on which the light source part is placed;
a case member with which the light source part placed on the placement region is covered by pressing an edge of an opening toward a circumferential region of the placement surface which is located around the placement region; and
a wiring board which is connected to the light source part and extends from the light source part to an outside of the placement surface along the placement surface,
wherein the light source part includes a substrate and a connector which is installed in a main surface of the substrate and connected to the wiring board,
the connector is located at an interval from the placement region in a direction away therefrom by bringing a surface of the substrate which faces an opposite side to the main surface into contact with the placement region, and
the circumferential region is located at an interval from the placement region in a direction away therefrom by providing a step between the circumferential region and the placement region.
